(19) United States
(12) Patent Application Publication
(10) Pub. No.: US 2026/0362994 A1
(43) Pub. Date: Nov. 12, 2026

(54) DEPOSITING FILMS WITH CONCENTRATION GRADIENTS IN A MOLD STACK

(71) Applicant: Lam Research Corporation, Fremont, CA (US)

(72) Inventors: Bryan Nicholas VOIGT, Newberg, OR (US); Keith FOX, Tigard, OR (US); Peter Andrew LANGAN, Tigard, OR (US)

(21) Appl. No.: 19/139,862

(22) PCT Filed: Dec. 13, 2023
(86) PCT No.: PCT/US2023/083857

§ 371 Date: Jun. 16, 2025

Related U.S. Application Data
(60) Provisional application No. 63/477,219, filed on Dec. 26, 2022.

(51) Int. Cl. H10P 14/60; C23C 16/24; C23C 16/40; C23C 16/44; C23C 16/455; C23C 16/46; C23C 16/52; H01J 37/32; H10P 14/20; H10P 14/69; H10P 14/692

(52) U.S. Cl. CPC H10P 14/662; C23C 16/24; C23C 16/401; C23C 16/4408; C23C 16/45529; C23C 16/45546; C23C 16/46; C23C 16/52; H10P 14/3411; H10P 14/3442; H10P 14/6336; H10P 14/6682; H10P 14/6903; H10P 14/69215; H01J 37/32082; H01J 2237/3321

(57) ABSTRACT

Examples are disclosed that relate to depositing films comprising a concentration gradient of an elemental component. One example provides a method for depositing a stack of films on a substrate in a processing chamber using chemical vapor deposition. The method comprises depositing a layer of silicon oxide on the substrate. The method further comprises controlling processing conditions to deposit a transition film onto the layer of silicon oxide while flowing polysilicon precursor into the processing chamber. The transition film comprising silicon oxide with an oxygen concentration gradient. The method further comprises depositing a layer of silicon onto the transition film.

### BACKGROUND

Alternating stacks of material layers, sometimes referred to as “mold stacks,” are often used to form 3-dimensional (3D) integrated circuits. Example 3D integrated circuits include 3D NAND memory, 3D NOR memory, and 3D DRAM.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to depositing layers of materials comprising composition gradients of elemental components. One example provides a method for depositing a stack of films on a substrate in a processing chamber using chemical vapor deposition (CVD). The method comprises depositing a layer of silicon oxide on the substrate. The method further comprises controlling processing conditions to deposit a transition film onto the layer of silicon oxide while flowing a polysilicon precursor into the processing chamber. The transition film comprises silicon oxide with an oxygen concentration gradient. The method further comprises depositing a layer of silicon onto the transition film.

In some such examples, controlling processing conditions to deposit the transition film comprises flowing an oxidizer into the processing chamber, after flowing the oxidizer into the processing chamber, flowing a purge gas into the chamber to remove a portion of the oxidizer from the processing chamber, and flowing the polysilicon precursor into the processing chamber.

In some such examples, flowing the purge gas into the processing chamber additionally or alternatively comprises flowing the purge gas into the processing chamber for a duration of 0.75 seconds or less.

In some such examples, flowing the oxidizer into the processing chamber additionally or alternatively comprises flowing at least one of oxygen, ozone, water vapor, hydrogen peroxide, or nitrous oxide into the processing chamber.

In some such examples, controlling processing conditions to deposit the transition film additionally or alternatively comprises flowing an oxidizer with the polysilicon precursor into the processing chamber and ramping down a flow rate of the oxidizer during deposition of the transition film.

In some such examples, the polysilicon precursor additionally or alternatively comprises at least one of silane, disilane, trisilane, or a halosilane.

In some such examples, controlling processing conditions to deposit the transition film additionally or alternatively comprises depositing the transition film comprising a thickness of 10 Å or less.

In some such examples, the method additionally or alternatively comprises ramping a flow rate of an n-type dopant precursor into the processing chamber while flowing the polysilicon precursor into the processing chamber to deposit the layer of silicon.

Another example provides a method for depositing a stack of films on a substrate disposed in a processing chamber using CVD. The method comprises depositing a layer of silicon comprising an n-type dopant concentration gradient on the substrate disposed in the processing chamber. The layer of silicon comprising the n-type dopant concentration gradient can be annealed to form a layer of polysilicon. Depositing the layer of silicon comprising the n-type dopant concentration gradient comprises flowing a polysilicon precursor into the processing chamber, and while flowing the polysilicon precursor into the processing chamber, ramping a flow rate of an n-type dopant-containing precursor flowing into the processing chamber. The method further comprises depositing a layer of silicon oxide on the layer of silicon comprising the n-type dopant concentration gradient.

In some such examples, the layer of silicon oxide is a second layer of silicon oxide, and depositing the layer of silicon additionally or alternatively comprises forming the layer of silicon on a first layer of silicon oxide.

In some such examples, ramping the flow rate of the n-type dopant-containing precursor additionally or alternatively comprises ramping up the flow rate from a relatively lower flow rate up to a relatively higher flow rate.

In some such examples, the relatively higher flow rate additionally or alternatively is within a range of 100 standard cm³ per minute (sccm) to 1000 sccm.

In some such examples, the method additionally or alternatively comprises, while flowing the polysilicon precursor into the processing chamber, flowing the n-type dopant-containing precursor into the processing chamber at a constant flow rate before or after ramping.

In some such examples, ramping the flow rate additionally or alternatively comprises linearly ramping the flow rate.

In some such examples, the n-type dopant-containing precursor additionally or alternatively comprises phosphine.

Another example provides a CVD tool. The CVD tool comprises a processing chamber. The CVD tool further comprises a substrate support disposed in the processing chamber. The CVD tool further comprises a substrate heater configured to heat a substrate disposed on the substrate support. The CVD tool further comprises a polysilicon precursor source. The CVD tool further comprises an oxidizer source. The CVD tool further comprises flow control hardware fluidly connecting the polysilicon precursor source and the oxidizer source to the processing chamber. The CVD tool further comprises an exhaust system. The CVD tool further comprises a controller configured to operate the substrate heater to heat a substrate on the substrate support, the substrate comprising a layer of silicon oxide. The controller is further configured to operate the flow control hardware to deposit a transition film on the layer of silicon oxide while flowing the polysilicon precursor into the processing chamber. The transition film comprises silicon oxide with an oxygen concentration gradient. The controller is further configured to operate the flow control hardware to flow the polysilicon precursor into the processing chamber to deposit a layer of silicon onto the transition film.

In some such examples, the controller is configured to operate the flow control hardware to deposit the transition film by operating the flow control hardware to flow the oxidizer into the processing chamber, after flowing the oxidizer, purge the processing chamber to remove some of the oxidizer from the processing chamber, and flow the polysilicon precursor into the processing chamber.

In some such examples, the controller additionally or alternatively is configured to operate the flow control hardware to deposit the transition film by operating the flow control hardware to flow the oxidizer with the polysilicon precursor into the processing chamber and ramp down a flow rate of the oxidizer.

In some such examples, the CVD tool additionally or alternatively comprises an n-type dopant source comprising an n-type dopant, the flow control hardware fluidly connecting the n-type dopant source to the processing chamber. The controller is further configured to, while flowing the polysilicon precursor into the processing chamber, ramp a flow rate of the n-type dopant into the processing chamber to deposit the layer of silicon, the layer of silicon comprising an n-type dopant concentration gradient.

In some such examples, the n-type dopant additionally or alternatively comprises at least one of phosphorus, arsenic, or antimony.

### BRIEF DESCRIPTION OF THE DRAWINGS

FIG. 1 shows a flow diagram of an example method for forming a material layer with an n-type dopant concentration gradient.

FIGS. 2A-2E schematically show structures formed in an example process that includes depositing a silicon layer comprising an n-type dopant concentration gradient.

FIG. 3 shows a flow diagram of an example method for forming a transition layer on a layer of silicon oxide and depositing a layer of silicon on the transition layer.

FIGS. 4A-4C schematically show structures formed in an example process that includes depositing a transition film onto a silicon oxide layer followed by deposition of a silicon layer on the silicon oxide layer.

FIG. 5 shows a schematic view of an example stack of alternating material layers that include concentration gradients.

FIG. 6 schematically shows an example processing tool for performing chemical vapor deposition.

FIG. 7 shows a block diagram of an example computing system.

### DETAILED DESCRIPTION

The term “chemical vapor deposition” (CVD) generally represents a process in which a solid phase film is formed on a substrate by directing a flow of one or more precursor gases over the substrate surface under processing conditions configured to cause the chemical conversion of the precursor gases to the solid phase film.

The term “concentration gradient” generally represents a change in the concentration of an elemental component of a film through a film thickness.

The term “flow control hardware” generally represents components configured to place one or more chemical sources in fluid connection with a processing chamber. Flow control hardware can comprise one or more mass flow controllers and/or valves, for example. Example chemical sources include film precursor sources, purge gas sources, and reactant gas sources.

The term “n-type dopant” generally represents an element that, when added to a semiconductor, forms an n-type semiconductor material. N-type dopants in silicon include phosphorus (P), arsenic (As), and antimony (Sb).

The term “n-type dopant precursor” generally represents a chemical substance that comprises an n-type dopant and can be introduced into a processing chamber with a polysilicon precursor to form a silicon layer comprising the n-type dopant.

The term “oxidizer” generally represents an oxygen-containing chemical that can react with a silicon oxide precursor to form a film of silicon oxide. Examples include oxygen (O₂), ozone (O₃), water vapor (H₂O), hydrogen peroxide (H₂O₂), and nitrous oxide (N₂O).

The term “plasma” generally represents a gaseous phase of matter comprising cations and free electrons.

The term “point-of-use valve manifold” (PVM) generally represents flow control hardware of a processing tool for controlling flow of one or more gases into a processing chamber. A PVM can comprise valves disposed closely to a gas inlet of a processing chamber such that flow rates of a respective plurality of gases can be controlled into that the processing chamber with substantial precision.

The term “polysilicon precursor” generally represents a silicon-containing precursor that can react to form a layer of silicon in a chemical vapor deposition process, wherein the layer of silicon can be amorphous, and can be annealed to form polycrystalline silicon (polysilicon) in a later processing step. Example polysilicon precursors include silane, disilane, trisilane, and halosilanes. A polysilicon precursor also can be used to deposit other films, such as a layer of silicon oxide or a transition film.

The term “purge” and variants thereof generally represent a process where at least a portion of reactive gas is removed from a processing chamber. The term “purge gas” generally represents any suitable inert gas that can be used to purge a processing chamber. Examples include hydrogen, helium, neon, nitrogen, argon, krypton, and xenon.

The term “ramp” and variants thereof generally represent a change that is either increasing or decreasing. “Ramping up” a flow rate refers to increasing the flow rate. “Ramping down” a flow rate refers to decreasing the flow rate. Similarly, a partial pressure of a gas can be ramped up or ramped down.

The term “silicon oxide precursor” generally represents any material that can be introduced into a processing chamber in a gas phase to form a silicon oxide film on a substrate. In some examples, a silicon oxide precursor can also be a polysilicon precursor. Example film precursors for forming silicon oxide films using CVD can comprise materials having the general structure:

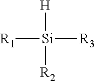

where R₁, R₂ and R₃ can be the same or different substituents. In various examples, R₁, R₂, and R₃ can include silanes, siloxy groups, amines, halides, hydrogen, or organic groups such as alkylamines, alkoxy, alkyl, alkenyl, alkynyl, and cyclic groups (such as aromatic groups).

In some examples, the silicon oxide precursor is an alkoxysilane. Alkoxysilanes that can be used include those having a composition of Hₓ—Si—(OR)_{y}, where x=1-3, x+y=4 and each R is a substituted or unsubstituted alkyl, substituted or unsubstituted alkenyl, substituted or unsubstituted alkynyl, or substituted or unsubstituted aromatic group; and Hₓ(RO)_{y}, —Si—Si—(OR)_{y}Hₓ, where each R is a substituted or unsubstituted alkyl, substituted or unsubstituted alkenyl, substituted or unsubstituted alkynyl, or substituted or unsubstituted aromatic group. Example alkoxysilanes include tetramethoxysilane (TMOS), diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon oxide precursor is a siloxane. Siloxanes include materials having Si—O—Si linkages. Example siloxanes include octamethylcyclotetrasiloxane (OMCTS), octamethoxydodecasiloxane (OMODDS), and tetramethylcyclotetrasiloxane (TMCTS).

In some examples, the silicon oxide precursor is an aminosilane. Aminosilanes include materials having the general formula Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group. Example aminosilanes include bisdiethylaminosilane, diisopropylaminosilane, bis(t-butylamino)silane (BTBAS), di-sec-butylaminosilane, and tris(dimethylamino)silane (3DMAS).

In some examples, the silicon oxide precursor can be a halosilane. In some examples, a halosilane can comprise at least one hydrogen atom. Such a silane can have a chemical formula of SiXₐH_{y} where y=1-3, a+y=4. Examples of halosilanes can include dichlorosilane (H₂SiCl₂), hexachlorodisilane (Si₂Cl₆), and diiodosilane (H₂SiI₂).

More specific examples of silicon oxide precursors include polysilanes (SiₙH₂ₙ₊₂, where n≥1, such as silane, disilane, trisilane, and tetrasilane), trisilylamine, tetraethyl orthosilicate (TEOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, triethoxysiloxane (TRIES), and tetraoxymethylcyclotetrasiloxane (TOMCTS).

The terms “stack” and “mold stack” generally represent a stack of alternating layers of different materials. Examples can include an “OP stack” comprising alternating layers of silicon oxide and polysilicon. An OP stack can be formed by depositing alternating layers of silicon oxide and amorphous silicon on a substrate, and then annealing the substrate to form layers of polysilicon from the layers of silicon. A layer of amorphous silicon also is referred to herein as a layer of silicon.

The term “transition film” generally represents a layer of silicon oxide comprising an oxygen concentration gradient.

The term “within a range” of X to Y generally represents a range inclusive of the values X and Y.

The term “3D NAND” is an abbreviation of three-dimensional NOT AND, and generally represents memory architecture based upon NOT AND logic gates.

The term “3D NOR” is an abbreviation of three-dimensional NOT OR, and generally represents memory architecture based upon NOT OR logic gates.

The term “3D DRAM” is an abbreviation of three-dimensional dynamic random access memory.

As described above, a mold stack is an alternating stack of material layers, which can be used to form 3-dimensional (3D) integrated circuits. Some mold stacks can comprise layers of silicon oxide (SiO₂) alternating with layers of polycrystalline silicon (polysilicon). Such stacks can be referred to as OP stacks, where “O” represents the “oxide” or SiO₂ layer and “P” represents the “poly” or polysilicon layer. OP stacks can be used to form three-dimensional (3D) memory structures such as 3D NAND, 3D NOR, or 3D DRAM structures.

However, OP stacks can suffer from weak adhesion at the interfaces between silicon oxide layers and polysilicon layers. Weak interfacial adhesion can lead to delamination, shredding, and failure of the device. Various interfacial treatments can be performed to increase interfacial adhesion. For example, one strategy is to nitridate the interface layer between the oxide layer and polysilicon layer. Nitridating treatments can include coating a surface with nitrogen prior to depositing a next layer. Such interfacial treatments can form chemical bridges (e.g., a silicon nitride bridge) across an interface. This can improve adhesion compared to examples that omit interfacial treatments.

However, the presence of nitrogen can potentially degrade device performance. Accordingly, examples are disclosed that relate to forming OP stacks that avoid the use of an interfacial nitridation step. Briefly, the disclosed examples comprise concentration gradients of various elements in material layers. The concentration gradients can help improve adhesion between silicon oxide and polysilicon layers in the OP stacks. Briefly, one example comprises using chemical vapor deposition (CVD) to deposit a layer of silicon comprising an n-type dopant concentration gradient on a substrate. The layer of silicon can be deposited by ramping a flow rate of an n-type dopant precursor while flowing a polysilicon precursor to form a layer of silicon comprising a concentration gradient. The flow rate of the n-type dopant precursor can be ramped up or ramped down to produce a positive or negative concentration gradient, respectively. Then, a layer of silicon oxide is deposited on the layer of silicon. The substrate later can be annealed to convert the layer of silicon from amorphous to polysilicon. The n-type dopant concentration gradient helps improve adhesion between the layer of silicon and the overlying layer of silicon oxide compared to examples that lack a concentration gradient. Further, use of the n-type dopant in the silicon layer can help to avoid the use of nitridation of the silicon layer surface as an adhesion strategy. This can help to improve device performance.

Examples are also disclosed that relate to forming a transition film between a layer of silicon oxide and a layer of silicon. The transition film comprises silicon oxide with an oxygen concentration gradient that transitions from silicon oxide to silicon. The transition film is deposited on a layer of silicon oxide by flowing a polysilicon precursor while controlling processing conditions to form the gradient. As described in more detail below, processing conditions can be controlled by ramping down a flow rate of an oxidizer, or by performing a relatively short purge to remove a portion of the oxidizer from the processing chamber. After forming the transition film, polysilicon precursor is flowed into the chamber to deposit a silicon layer onto the transition film. The transition film helps improve adhesion between the underlying layer of silicon oxide and the overlying layer of silicon compared to examples that lack transition films.

As such, OP stacks can be fabricated that include a layer of polysilicon comprising an n-type dopant concentration gradient, a transition film comprising an oxygen concentration gradient, or a combination of both the n-type dopant gradient in the polysilicon layer and the oxygen concentration gradient in the transition layer. The examples disclosed herein can help improve adhesion in OP stacks while maintaining desired film properties. For example, a polysilicon layer initially deposited with an n-type dopant concentration gradient can have a sheet resistance that is substantially similar to a sheet resistance of polysilicon initially deposited with a homogeneous dopant concentration. Further, as mentioned above, interfacial nitriding treatments can be avoided, leading to improved device performance.

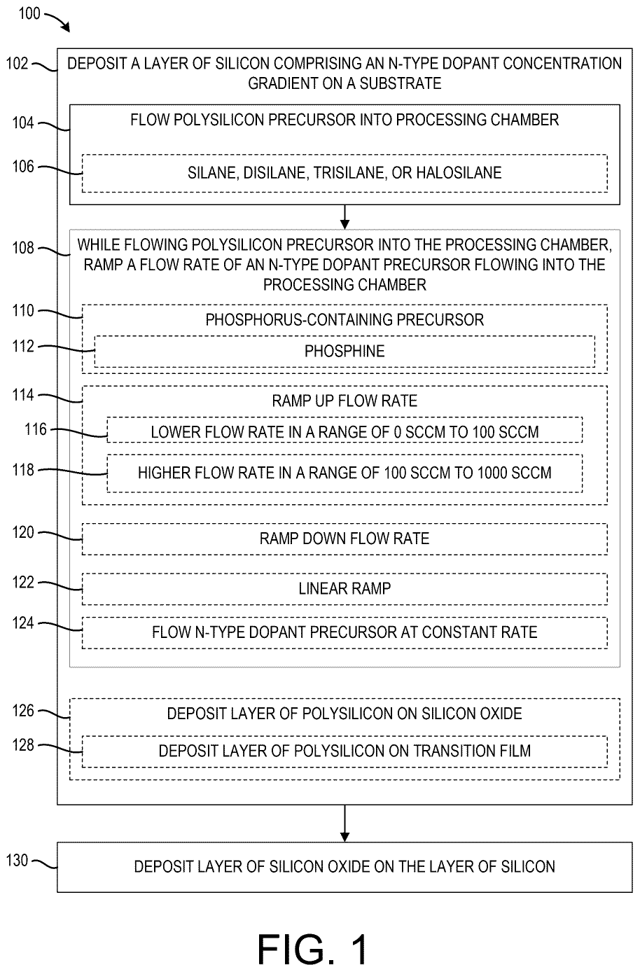

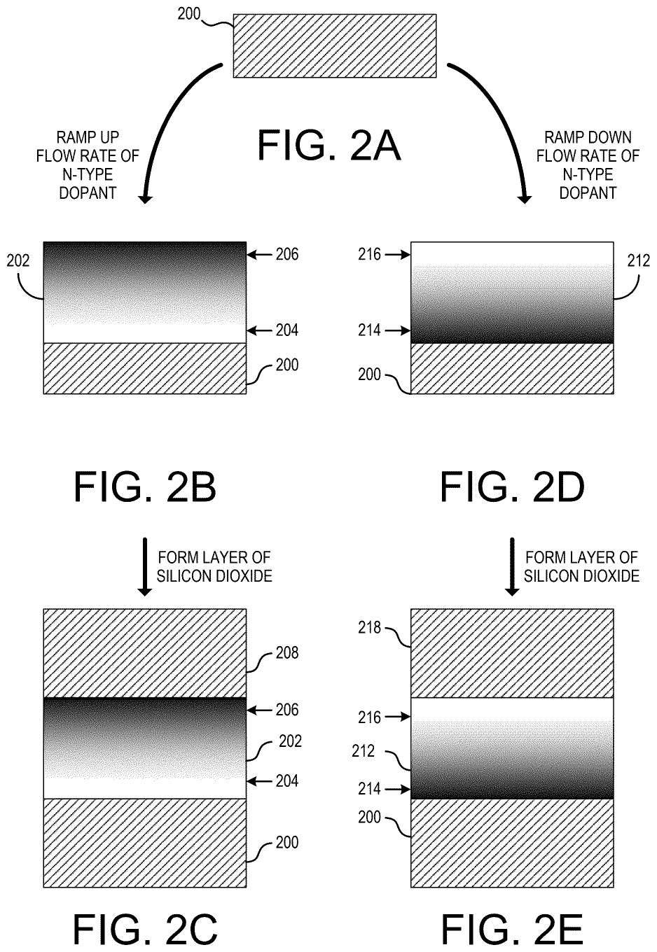

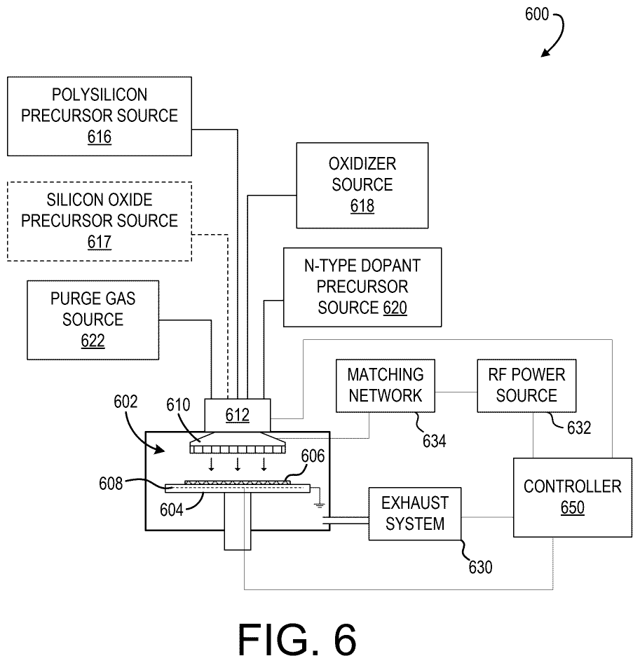

FIG. 1 shows a flow diagram for an example method 100 for depositing a stack of films on a substrate in a processing chamber using chemical vapor deposition. More particularly, FIG. 1 illustrates forming a silicon film comprising an n-type dopant concentration gradient. FIGS. 2A-2E schematically show example substrate structures that can be formed in such a process. Method 100 can be used to process a substrate in a processing chamber of a chemical vapor deposition tool. Example processing tools are discussed below with regard to FIG. 6.

Method 100 comprises, at step 102, depositing a layer of silicon comprising an n-type dopant concentration gradient on a substrate. The substrate can comprise a layer of silicon oxide in an OP stack. Step 102 comprises, at 104, flowing a polysilicon precursor into the processing chamber to react the polysilicon precursor on the substrate. Heat and/or plasma can be used to facilitate chemical conversion of the polysilicon precursor to a layer of silicon. The layer of silicon can be formed using any silicon oxide precursor that is suitable for forming amorphous silicon with an n-type dopant. In some examples, at 106, the polysilicon precursor comprises one or more of silane, disilane, trisilane, or a halosilane. Suitable halosilanes can include dichlorosilane, hexachlorodisilane, and diiodosilane.

Step 102 further comprises, at 108, while flowing the polysilicon precursor into the processing chamber, ramping a flow rate of an n-type dopant precursor flowing into the processing chamber. Any suitable n-type dopant precursor can be used. In some examples, at 110, the n-type dopant precursor comprises a phosphorus-containing dopant precursor. In some examples, at 112, the phosphorus-containing dopant precursor comprises phosphine. Further examples of phosphorus-containing dopant precursors can include substituted phosphines such as phosphorus trichloride or other halosubstituted phosphines. Other examples of n-type dopant precursors can include arsenic-containing dopant precursors and antimony-containing dopant precursors. Examples include arsine (AsH₃), arsenic halides such as AsX₃ (X=F, Cl, Br, I), and stibine (SbH₃).

In various examples, the flow rate of the n-type dopant precursor can be ramped up (increasing with time) or ramped down (decreasing with time). Ramping up refers to a period where a flow rate Q is increasing such that ΔQ≥0 over a time period. Ramping up a flow rate of a gas into a processing chamber can have an effect of ramping up the partial pressure of the gas in the processing chamber. Ramping down refers to a period where the flow rate Q is decreasing such that ΔQ≤0 over a time period. Ramping down a flow rate of a gas into a processing chamber can have an effect of ramping down the partial pressure of the gas in the processing chamber. In some examples, a baseline flow rate of the n-type dopant precursor can be established prior to ramping up or ramping down the flow rate. The flow of the n-type dopant precursor can be shut off after ramping the flow rate to deposit the layer of silicon comprising the n-dopant concentration gradient.

Thus, continuing with FIG. 1, in some examples, at 114, method 100 comprises ramping up the flow rate of the n-type dopant precursor. FIGS. 2A-2C schematically show example structures that can be formed by ramping up a flow rate of an n-type dopant precursor. First, FIG. 2A shows a silicon oxide substrate 200 on which a layer of silicon is to be deposited for forming a polysilicon layer. Silicon oxide substrate 200 can be disposed on other underlying layers that are not depicted in FIGS. 2A-2E. Examples include a silicon wafer, or an underlying silicon layer of an OP stack. Silicon oxide substrate 200 represents an O layer in an OP stack.

FIG. 2B shows a structure after forming a layer of silicon 202 on the silicon oxide substrate 200. Layer of silicon 202 comprises an n-type dopant concentration gradient formed by ramping up the flow rate of an n-type dopant precursor. In this example, the n-type dopant concentration increases with the thickness of the layer of silicon 202. As such, a concentration of the n-type dopant at a first depth 204 is less than a concentration of the n-type dopant at a second depth 206. Layer of silicon 202 can comprise a sheet resistance that is substantially similar to a sheet resistance of uniformly n-doped polysilicon. In some examples, the sheet resistance of polysilicon deposited with an n-type dopant concentration gradient can be within 2.5% of a sheet resistance of polysilicon deposited with a relatively homogeneous concentration of the n-type dopant.

Returning to FIG. 1, the flow rate of the n-type dopant can be ramped between any suitable beginning and end values. In some examples, at 116, a lower flow rate at which a ramp up starts can be within a range of 0 standard cubic centimeters per minute (sccm) to 400 sccm. Further, in more specific examples, the lower flow rate is within a range of 0 sccm to 100 sccm.

Further, in some examples, the higher flow rate to which the flow rate is ramped can be within a range of 100 sccm to 2000 sccm. In some more specific examples, the higher flow rate to which the flow rate is ramped can be within a range of 100 sccm to 1000 sccm. In other examples, flow rates outside of these ranges can be used.

In other examples, at 120, method 100 comprises ramping down the flow rate of the n-type dopant precursor. FIGS. 2A, 2D, and 2E show example structures formed by ramping down the flow rate of an n-type precursor while depositing a silicon layer using a polysilicon precursor. As mentioned above, FIG. 2A shows a silicon oxide substrate 200, which can represent an O layer in an OP stack. Next, FIG. 2D shows a layer of silicon 212 formed on the silicon oxide substrate 200. Layer of silicon 212 comprises an n-type dopant concentration gradient. Due to ramping down the flow rate of the n-type dopant at 120, the concentration decreases with increasing thickness of the layer of silicon 212. As such, a concentration of the n-type dopant at a first depth 214 is greater than a concentration of the n-type dopant at a second depth 216. A higher flow rate at which the n-type dopant precursor flow starts, and a lower flow rate at which the n-type dopant precursor flow ends, can be within the example ranges stated above at 116 and 118.

In some examples, at 122, ramping the flow rate comprises linearly ramping the flow rate. Linearly ramping the flow rate comprises increasing or decreasing the flow rate at a constant rate of change. In other examples, the rate of change of the flow rate can vary. In some examples, at 124, the method further comprises flowing the n-type dopant precursor at a constant flow rate. As described above, a constant flow rate can be used before or after ramping the flow rate.

As discussed above, the layer of silicon can be deposited on silicon oxide as part of a fabrication process for an OP stack. Thus, at 126, method 100 comprises depositing the layer of silicon on a layer of silicon oxide. In some such examples, at 128, the layer of silicon is deposited on a transition film. Transition films are discussed in more detail below.

Method 100 further comprises, at 130, depositing a layer of silicon oxide on the layer of silicon comprising the n-type dopant concentration gradient. FIGS. 2C and 2E illustrate a deposited layer of silicon oxide. FIG. 2C shows a layer of silicon oxide 208 deposited on the layer of silicon 202 having an n-type dopant concentration that increases as a function of increasing thickness. Similarly, FIG. 2E shows a layer of silicon oxide 218 deposited on the layer of silicon 212 having an n-type dopant concentration that decreases as a function of increasing thickness. As mentioned above, the n-type dopant concentration gradient can help improve adhesion between layers of polysilicon and silicon oxide. This can provide for sufficient adhesion to avoid delamination, shredding, and device failure while avoiding an interfacial nitriding step.

Returning to FIG. 1, any suitable silicon oxide precursor can be used to deposit the layer of silicon oxide at 130. In some examples, the silicon oxide precursor is an alkoxysilane. Alkoxysilanes that can be used include those having a composition of Hₓ—Si—(OR)_{y}, where x=1-3, x+y=4 and each R is a substituted or unsubstituted alkyl, substituted or unsubstituted alkenyl, substituted or unsubstituted alkynyl, or substituted or unsubstituted aromatic group; and Hₓ(RO)_{y}, —Si—Si—(OR)_{y}Hₓ, where each R is a substituted or unsubstituted alkyl, substituted or unsubstituted alkenyl, substituted or unsubstituted alkynyl, or substituted or unsubstituted aromatic group. Example alkoxysilanes include tetramethoxysilane (TMOS), diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon oxide precursor is a siloxane. Siloxanes include materials having Si—O—Si linkages. Example siloxanes include octamethylcyclotetrasiloxane (OMCTS), octamethoxydodecasiloxane (OMODDS), and tetramethylcyclotetrasiloxane (TMCTS).

In some examples, the silicon oxide precursor is an aminosilane. Aminosilanes include materials having the general formula Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group. Example aminosilanes include bisdiethylaminosilane, diisopropylaminosilane, bis(t-butylamino)silane (BTBAS), di-sec-butylaminosilane, and tris(dimethylamino)silane (3DMAS).

In some examples, the silicon oxide precursor can be a halosilane. In some examples, a halosilane can comprise at least one hydrogen atom. Such a silane can have a chemical formula of SiXₐH_{y} where y=1-3, a+y=4. Examples of halosilanes can include dichlorosilane (H₂SiCl₂), hexachlorodisilane (Si₂Cl₆), and diiodosilane (H₂SiI₂).

Further examples of silicon oxide precursors include polysilanes (Siₙ H₂ₙ₊₂, where n≥1, such as silane, disilane, trisilane, and tetrasilane), trisilylamine, tetraethyl orthosilicate (TEOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, triethoxysiloxane (TRIES), and tetraoxymethylcyclotetrasiloxane (TOMCTS).

An oxidizer also is introduced into the processing chamber to form the layer of silicon oxide. The oxidizer can comprise any suitable oxygen-containing chemical that can react with a silicon oxide precursor to form a film of silicon oxide. Examples of oxidizers can include oxygen, ozone, water vapor, hydrogen peroxide, and nitrous oxide.

As mentioned above, in some examples, a transition film can be used to improve adhesion between layers in an OP stack. A transition film comprises a region of silicon oxide with an oxygen concentration gradient. The transition film is formed on a layer of silicon oxide. Then, a layer of silicon can be deposited on the transition film. The transition film is deposited with a negative oxygen concentration gradient such that the oxygen concentration decreases as the transition film thickness increases.

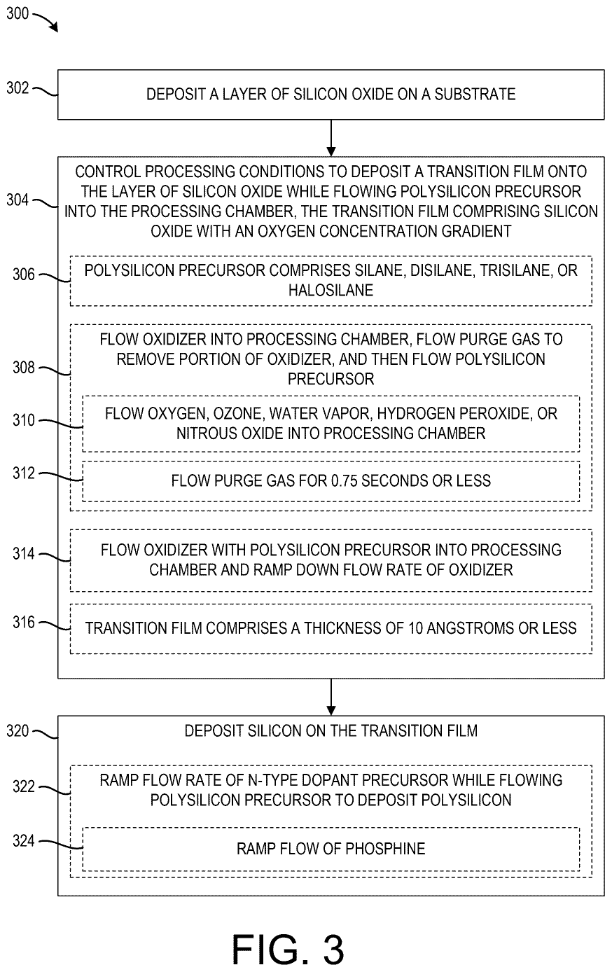

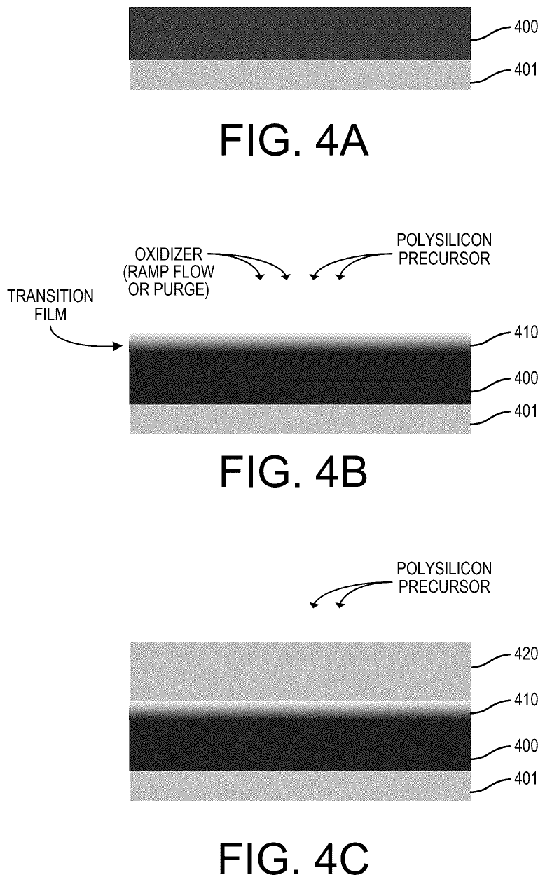

FIG. 3 shows a flow diagram of an example method 300 that includes forming a transition film comprising an oxygen concentration gradient. Method 300 can be used to deposit a stack of films on a substrate in a processing chamber of a CVD tool. FIGS. 4A-4C schematically show structures that can be formed in such a process. Examples of processing tools that can be used to perform method 300 are described in more detail below with regard to FIG. 6.

Method 300 comprises, at 302, depositing a layer of silicon oxide on a substrate. FIG. 4A shows an example layer of silicon oxide 400 formed on a substrate 401. The substrate can represent a silicon layer in an OP stack that will be converted to a polysilicon layer in a later annealing step. The layer of silicon oxide is deposited using CVD. Examples of silicon oxide precursors and oxidizers for forming silicon oxide films are described above. As mentioned above, heat and/or plasma can be used to facilitate the conversion of precursors to a film.

Method 300 further comprises, at 304, controlling processing conditions to deposit a transition film onto the layer of silicon oxide while flowing polysilicon precursor into the processing chamber. In some examples, at 306, the polysilicon precursor comprises one or more of silane, disilane, trisilane, or a halosilane. Example halosilanes include those listed above. The transition film formed at 304 comprises silicon oxide with an oxygen concentration gradient.

FIGS. 4A-4B show a transition film 410 deposited on the layer of silicon oxide 400. Transition film 410 comprises silicon oxide comprising an oxygen concentration gradient. As illustrated by a gradient in the illustrated shading, the oxygen concentration decreases as a function of increasing thickness of the transition film 410.

Processing conditions in the processing chamber can be controlled in any suitable manner to deposit transition film 410. Returning to FIG. 3, in some examples, at 308, controlling processing conditions comprises flowing an oxidizer into the processing chamber. In some examples, the oxidizer can comprise one or more of oxygen, ozone, water vapor, hydrogen peroxide, or nitrous oxide, as indicated at 310. After flowing the oxidizer, step 308 further comprises flowing a purge gas to remove a portion of the oxidizer. Examples of suitable purge gases can include helium, neon, nitrogen, argon, krypton, and xenon. Step 308 further comprises flowing polysilicon precursor into the processing chamber. As such, the polysilicon precursor can react with residual oxidizer in the processing chamber. As the residual oxidizer is consumed or evacuated, the transition film is deposited on the substrate as a layer of silicon oxide comprising an oxygen concentration gradient. After consuming the oxidizer, additional polysilicon precursor is deposited to form a layer of silicon. The layer of silicon can later be annealed to form a layer of polysilicon. Referring briefly to FIG. 4B, as oxygen concentration decreases, the transition film 410 transitions from silicon oxide to silicon.

In some examples, at 312, flowing the purge gas into the processing chamber comprises flowing the purge gas into the processing chamber for a duration of 0.75 seconds or less. In some examples, the purge gas is flowed for a duration of 0.5 seconds or less. In some examples, the purge gas is flowed for a duration of 0.25 seconds or less. A shorter purge can allow more oxidizer to remain in the processing chamber for reacting with the polysilicon precursor. In other examples, the purge gas can be flowed for a longer duration.

In further examples, a flow rate of the oxidizer can be ramped down to form the transition film. As such, at 314, controlling processing conditions to deposit the transition film optionally comprises flowing an oxidizer with the polysilicon precursor into the processing chamber and ramping down a flow rate of the oxidizer during deposition of the transition film. In some examples, the flow rate is ramped down and shut off within 1 second or less. In some examples, the flow rate is ramped down within 0.75 seconds, or within 0.5 seconds. In some examples, a flow rate of the polysilicon precursor can be ramped up as the flow rate of the oxidizer is ramped down.

The transition film can comprise any suitable thickness. The thickness of the transition film can be affected by various factors, such as a chamber pressure, a plasma power and/or frequency, a flow rate of the oxidizer, a flow rate of the polysilicon precursor, a purge duration, an amount of residual oxidizer remaining following a purge, and a flow rate ramping duration. In some examples, at 316, the transition film comprises a thickness of 10 Å or less. In other examples, a transition film can be deposited having suitable thickness of greater than 10 Å.

Continuing, method 300 comprises, at 320, depositing a layer of silicon onto the transition film. FIG. 4C illustrates such an example where polysilicon precursor is flowed to deposit a layer of silicon 420 on the transition film 410. Due to the transition film 410, adhesion between the layer of silicon 420 and the layer of silicon oxide 400 can be greater compared to examples that lack a transition film. As such, interfacial nitriding treatments can be avoided.

As discussed above, a layer of silicon can be formed having an n-type dopant concentration gradient. Thus, in some examples, at 322, method 300 further comprises ramping a flow rate of an n-type dopant precursor into the processing chamber while flowing the polysilicon precursor into the processing chamber to deposit polysilicon. In some examples, at 324, the n-type dopant precursor comprises phosphine. In other examples, any other suitable n-type dopant precursor can be used. Other example n-type dopant precursors are listed above. Examples of depositing a layer of silicon with an n-type dopant concentration gradient are described above with regard to method 100.

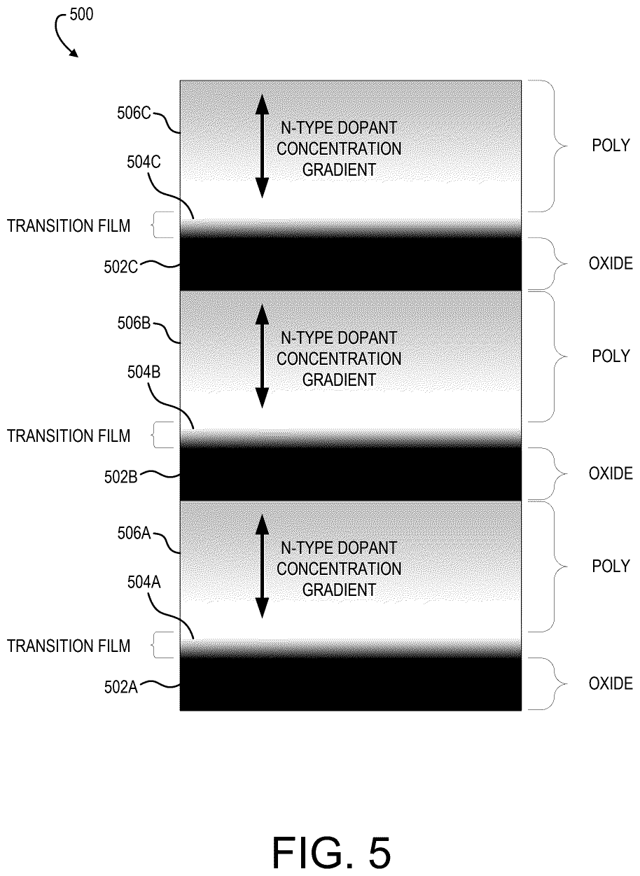

As mentioned above, transition films can be used in combination with layers of polysilicon comprising an n-type dopant concentration gradient to form OP stacks. Such examples can help improve adhesion between layers compared to examples that lack such concentration gradients. FIG. 5 shows a schematic view of an example OP stack 500 that includes transition films in addition to polysilicon with an n-type dopant concentration gradient. OP stack 500 can be formed using method 100 and method 300, for example, followed by annealing to convert amorphous silicon to polysilicon. OP stack 500 comprises layers of silicon oxide 502A-C. OP stack further comprises transition films 504A-C. OP stack further comprises layers of polysilicon 506A-C. The layers of polysilicon 506A-C each comprise an n-type dopant concentration gradient. Each layer of silicon independently can comprise an increasing concentration gradient (e.g., layer of silicon 202) or a decreasing concentration gradient (e.g., layer of silicon 212). While the example depicted in FIG. 5 shows three OP units (labeled A, B, C), in other examples, an OP stack can comprise any suitable number of layers.

FIG. 6 shows an example CVD tool 600 that can be used to deposit a transition film, a layer of silicon comprising an n-type dopant concentration gradient, and OP stacks. The CVD tool 600 comprises a processing chamber 602 and a substrate support 604 within the processing chamber. Substrate support 604 is configured to support a substrate 606 disposed within processing chamber 602. In some examples, substrate support 604 comprises a substrate heater 608. Substrate support 604 can comprise a pedestal, an electrostatic chuck pedestal, a showerhead pedestal, or any other suitable structure.

CVD tool 600 further comprises a processing gas inlet 610. Processing gas inlet 610 is configured to introduce chemical precursors into processing chamber 602. In some examples, processing gas inlet 610 comprises a showerhead.

CVD tool 600 further comprises flow control hardware 612. Flow control hardware 612 is connected to a polysilicon precursor source 616, an optional silicon oxide precursor source 617, an oxidizer source 618, an n-type dopant precursor source 620, and a purge gas source 622. Flow control hardware 612 is configured to place one or more chemical sources in fluid connection with processing chamber 602.

Polysilicon precursor source 616 can comprise any suitable chemical that can react to form a layer of silicon in a CVD process, wherein the layer of silicon can be amorphous, and can be annealed to form polysilicon in a later processing step. Suitable polysilicon precursors include silane, disilane, trisilane, and halosilanes. Examples of halosilanes can include dichlorosilane, hexachlorodisilane, and diiodosilane.

In some examples, polysilicon precursor source 616 also can be used to provide precursor for forming silicon oxide. In other examples, the optional silicon oxide precursor source can be used to form silicon oxide films. Optional silicon oxide precursor source 617 comprises any suitable precursor that can react to form silicon oxide in a CVD process. Examples of silicon oxide precursors for forming silicon oxide include tetraethyl orthosilicate, tetramethoxysilane, methylsilane, trimethylsilane, ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane, diethoxysilane, dimethoxymethylsilane, dimethoxysilane, methyl-diethoxysilane, methyl-dimethoxysilane, t-butoxydisilane, triethoxysilane, and trimethoxysilane.

In some examples, the silicon oxide precursor can be a siloxane. Example siloxanes include octamethylcyclotetrasiloxane, octamethoxydodecasiloxane, tetramethylcyclotetrasiloxane, triethoxysiloxane, and tetraoxymethylcyclotetrasiloxane.

Oxidizer source 618 comprises any suitable oxidizer that can be used to react with a polysilicon precursor to deposit silicon oxide in a CVD process. Examples can include oxygen, ozone, water vapor, hydrogen peroxide, and nitrous oxide.

The n-type dopant precursor source 620 comprises any suitable n-type dopant precursor. Examples can include phosphorus-containing dopant precursors, arsenic-containing dopant precursors, and antimony-containing dopant precursors. Examples of phosphorus-containing dopant precursors can include phosphine, methylphosphine, phosphorus trichloride, and methyldichlorophosphine. Examples of arsenic-containing dopant precursors can include arsine, alkyl arsines such as trimethyl arsine, and arsenic halides. Examples of antimony-containing dopant precursors can include stibine.

Purge gas source 622 can comprise any suitable inert gas. Examples include helium, neon, nitrogen, argon, krypton, and xenon.

Flow control hardware 612 is configured to control the flow of polysilicon precursor from polysilicon precursor source 616 into processing chamber 602. Flow control hardware 612 is further configured to control the flow of silicon oxide precursor from silicon oxide precursor source 617 into processing chamber 602. Similarly, flow control hardware 612 is configured to control the flow of oxidizer, n-type dopant precursor, and purge gas from respective sources into processing chamber 602. Flow control hardware 612 can comprise one or more mass flow controllers and/or valves to control flow rates of gases. In some examples, flow control hardware 612 comprises a point-of-use valve manifold (PVM). A PVM can comprise valves positioned close enough to processing gas inlet 610 such that flow rates of a respective plurality of gases flowing into processing chamber 602 can be controlled with substantial precision.

CVD tool 600 further comprises an exhaust system 630. Exhaust system 630 is configured to receive gas outflowing from processing chamber 602. In some examples, exhaust system 630 is configured to actively remove gas from processing chamber 602 and/or apply a partial vacuum. Exhaust system 630 can comprise any suitable hardware, including one or more pumps.

CVD tool 600 further comprises a radiofrequency (RF) power source 632 that is electrically connected to processing gas inlet 610. Radiofrequency power source 632 is configured to form a plasma between a pair of electrodes comprising processing gas inlet 610 and substrate support 606. A plasma can be used to facilitate conversion of one or more film precursors into reactive chemical species to form a film. In some examples, the plasma can comprise an inert diluent gas, such as an inert gas from purge gas source 622. CVD tool 600 can include a matching network 634 for impedance matching of the radiofrequency power source 632. Radiofrequency power source 632 can be configured for any suitable frequency (e.g., 400 kHz or 13.56 MHz as examples) and power (e.g., a power within a range of 0 to 6500 watts). In some examples, radiofrequency power source 632 is configured to operate at a plurality of different frequencies and/or powers. In other examples, a radiofrequency power source and matching network can be omitted. In yet other examples, a remote plasma generator can be used. A remote plasma generator generates reactive chemical species using a plasma that is locates away from a substrate being processed.

CVD tool 600 further comprises a controller 650 configured to control functions of the CVD tool 600. Controller 650 is operatively coupled to substrate heater 608, flow control hardware 612, and exhaust system 630. Controller 650 further can be operatively coupled to any other suitable component of CVD tool 600. Controller 650 is configured to control various functions of CVD tool 600 to form a stack of films on a substrate. For example, controller 650 is configured to operate substrate heater 608 to heat a substrate. Controller 650 is also configured to operate flow control hardware 612 to flow a polysilicon precursor at a selected flow rate into processing chamber 602. Controller 650 also is configured to operate flow control hardware 612 to flow silicon oxide precursor at a selected flow rate into processing chamber 602. Controller 650 also is configured to operate flow control hardware 612 to flow oxidizer at a selected flow rate into processing chamber 602. Controller 650 also is configured to operate flow control hardware 612 to flow n-type dopant precursor at a selected flow rate into processing chamber 602.

Controller 650 is also configured to operate exhaust system 630 to remove gases from processing chamber 602. Controller 650 is further configured to operate flow control hardware 612 and exhaust system 630 to maintain a selected pressure within processing chamber 602.

Controller 650 also is configured to operate flow control hardware 612 to ramp a flow rate of a gas flowing into processing chamber 602. Controller 650 also is configured to purge processing chamber 602. For example, controller 650 is configured to operate flow control hardware 612 to flow purge gas for a selected duration into processing chamber 602 and/or control exhaust system 630 to remove gases from the processing chamber. Controller 650 also is configured to operate radiofrequency power source 632 to form a plasma.

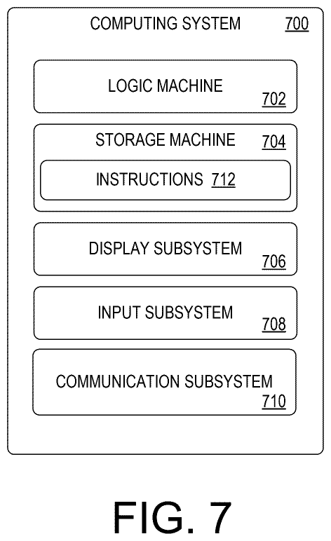

Controller 650 further is configured to control processing conditions (e.g., pressure, radiofrequency power, gas flow) to control conformality, thickness, and other film characteristics. Controller 650 is further configured to control any other functions of CVD tool 600. Controller 650 also is configured to operate CVD tool 600 to enact any of the methods disclosed herein. Controller 650 can comprise any suitable computing system. An example computing system is described below at FIG. 7.

As such, the disclosed examples provide for depositing stacks of films with improved interfacial adhesion compared to other stacks. A stack can be formed that includes a layer of polysilicon (after annealing) comprising an n-type dopant concentration gradient. An OP stack can be formed that includes a transition film comprising silicon oxide with an oxygen concentration gradient. Further, an OP stack can be formed that includes a combination of these features. The examples disclosed herein can help improve adhesion in OP stacks without significant effects to film properties. Improved adhesion can help avoid interfacial nitriding treatments, which also can improve device performance compared to devices that use nitridation between OP stack layers for adhesion.

In some examples, the methods and processes described herein can be tied to a computing system of one or more computing devices. In particular, such methods and processes can be implemented as a computer-application program or service, an application-programming interface (API), a library, and/or other computer-program product.

FIG. 7 schematically shows a non-limiting example of a computing system 700 that can enact one or more of the methods and processes described above. Computing system 700 is shown in simplified form. Computing system 700 can take the form of one or more personal computers, workstations, computers integrated with substrate processing tools, and/or network accessible server computers.

Computing system 700 includes a logic machine 702 and a storage machine 704. Computing system 700 can optionally include a display subsystem 706, input subsystem 708, communication subsystem 710, and/or other components not shown in FIG. 7. Controller 650 is an example of computing system 700.

Logic machine 702 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 704 includes one or more physical devices configured to hold instructions 712 executable by the logic machine to implement the methods and processes described herein. When such methods and processes are implemented, the state of storage machine 704 can be transformed—e.g., to hold different data.

Storage machine 704 can include removable and/or built-in devices. Storage machine 704 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 704 can include volatile, nonvolatile, dynamic, static, read/write, read-only, random-access, sequential-access, location-addressable, file-addressable, and/or content-addressable devices.

It will be appreciated that storage machine 704 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 702 and storage machine 704 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 706 can be used to present a visual representation of data held by storage machine 704. This visual representation can take the form of a graphical user interface (GUI). As the herein described methods and processes change the data held by the storage machine, and thus transform the state of the storage machine, the state of display subsystem 706 can likewise be transformed to visually represent changes in the underlying data. Display subsystem 706 can include one or more display devices utilizing virtually any type of technology. Such display devices can be combined with logic machine 702 and/or storage machine 704 in a shared enclosure, or such display devices can be peripheral display devices.

When included, input subsystem 708 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 710 can be configured to communicatively couple computing system 700 with one or more other computing devices. Communication subsystem 710 can include wired and/or wireless communication devices compatible with one or more different communication protocols. As non-limiting examples, the communication subsystem can be configured for communication via a wireless telephone network, or a wired or wireless local- or wide-area network. In some examples, the communication subsystem can allow computing system 700 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for depositing a stack of films on a substrate in a processing chamber using chemical vapor deposition, the method comprising:
depositing a layer of silicon oxide on the substrate;
controlling processing conditions to deposit a transition film onto the layer of silicon oxide while flowing a polysilicon precursor into the processing chamber, the transition film comprising silicon oxide with an oxygen concentration gradient; and
depositing a layer of silicon onto the transition film.

2. The method of claim 1, wherein controlling processing conditions to deposit the transition film comprises:
flowing an oxidizer into the processing chamber,
after flowing the oxidizer into the processing chamber, flowing a purge gas into the processing chamber to remove a portion of the oxidizer from the processing chamber, and
flowing the polysilicon precursor into the processing chamber.

3. The method of claim 2, wherein flowing the purge gas into the processing chamber comprises flowing the purge gas into the processing chamber for a duration of 0.75 seconds or less.

4. The method of claim 2, wherein flowing the oxidizer into the processing chamber comprises flowing at least one of oxygen, ozone, water vapor, hydrogen peroxide, or nitrous oxide into the processing chamber.

5. The method of claim 1, wherein controlling processing conditions to deposit the transition film comprises flowing an oxidizer with the polysilicon precursor into the processing chamber and ramping down a flow rate of the oxidizer during deposition of the transition film.

6. The method of claim 1, wherein the polysilicon precursor comprises at least one of silane, disilane, trisilane, or a halosilane.

7. The method of claim 1, wherein controlling processing conditions to deposit the transition film comprises depositing the transition film comprising a thickness of 10 Å or less.

8. The method of claim 1, further comprising ramping a flow rate of an n-type dopant precursor into the processing chamber while flowing the polysilicon precursor into the processing chamber to deposit the layer of silicon.

9. A method for depositing a stack of films on a substrate disposed in a processing chamber using chemical vapor deposition, the method comprising:
depositing a layer of silicon comprising an n-type dopant concentration gradient on the substrate disposed in the processing chamber by:
flowing a polysilicon precursor into the processing chamber, and
while flowing the polysilicon precursor into the processing chamber, ramping a flow rate of an n-type dopant-containing precursor flowing into the processing chamber to form the layer of silicon; and
depositing a layer of silicon oxide on the layer of silicon comprising the n-type dopant concentration gradient.

10. The method of claim 9, wherein the layer of silicon oxide is a second layer of silicon oxide, and forming the layer of silicon comprises forming the layer of silicon on a first layer of silicon oxide.

11. The method of claim 9, wherein ramping the flow rate of the n-type dopant-containing precursor comprises ramping up the flow rate from a relatively lower flow rate to a relatively higher flow rate.

12. The method of claim 11, wherein the relatively higher flow rate is within a range of 100 standard cubic centimeter per minute (sccm) to 1000 sccm.

13. The method of claim 9, further comprising, while flowing the polysilicon precursor into the processing chamber, flowing the n-type dopant-containing precursor into the processing chamber at a constant flow rate before or after ramping.

14. The method of claim 9, wherein ramping the flow rate comprises linearly ramping the flow rate.

15. The method of claim 9, wherein the n-type dopant-containing precursor comprises phosphine.

16. A chemical vapor deposition tool, comprising:
a processing chamber;
a substrate support disposed in the processing chamber;
a substrate heater configured to heat a substrate disposed on the substrate support;
a polysilicon precursor source comprising a polysilicon precursor;
an oxidizer source comprising an oxidizer;
flow control hardware fluidly connecting the polysilicon precursor source and the oxidizer source to the processing chamber;
an exhaust system; and
a controller configured to
operate the substrate heater to heat the substrate on the substrate support, the substrate comprising a layer of silicon oxide,
operate the flow control hardware to deposit a transition film on the layer of silicon oxide while flowing the polysilicon precursor into the processing chamber, the transition film comprising silicon oxide with an oxygen concentration gradient, and
operate the flow control hardware to flow the polysilicon precursor into the processing chamber to deposit a layer of silicon onto the transition film.

17. The chemical vapor deposition tool of claim 16, wherein the controller is configured to operate the flow control hardware to deposit the transition film by operating the flow control hardware to:
flow the oxidizer into the processing chamber,
after flowing the oxidizer, purge the processing chamber to remove some of the oxidizer from the processing chamber, and
flow the polysilicon precursor into the processing chamber.

18. The chemical vapor deposition tool of claim 16, wherein the controller is configured to operate the flow control hardware to deposit the transition film by operating the flow control hardware to flow the oxidizer with the polysilicon precursor into the processing chamber and ramp down a flow rate of the oxidizer.

19. The chemical vapor deposition tool of claim 16, further comprising an n-type dopant source comprising an n-type dopant, the flow control hardware fluidly connecting the n-type dopant source to the processing chamber,
wherein the controller is further configured to, while flowing the polysilicon precursor into the processing chamber, ramp a flow rate of the n-type dopant into the processing chamber to deposit the layer of silicon, the layer of silicon comprising an n-type dopant concentration gradient.

20. The chemical vapor deposition tool of claim 19, wherein the n-type dopant comprises at least one of phosphorus, arsenic, or antimony.
